(19) United States
(12) Patent Application Publication
(10) Pub. No.: US 2024/0324460 A1
(43) Pub. Date: Sep. 26, 2024

(54) B/N ORGANIC ELECTROLUMINESCENT MATERIAL AND PREPARATION METHOD AND USE THEREOF

(71) Applicant: SOOCHOW UNIVERSITY, Wujiang (CN)

(72) Inventors: Xiaohong ZHANG, Wujiang (CN); Xiaochun Fan, Wujiang (CN); Kai Wang, Wujiang (CN)

(21) Appl. No.: 18/672,801

(22) Filed: May 23, 2024

Related U.S. Application Data
(63) Continuation of application No. PCT/CN2022/101011, filed on Jun. 24, 2022.

(30) Foreign Application Priority Data
Nov. 29, 2021 (CN) 202111439232.3

(51) Int. Cl. H10K 85/60; C07F 5/02; C09K 11/06; H10K 50/11; H10K 101/20

(52) U.S. Cl. CPC H10K 85/658; C07F 5/027; C09K 11/06; C09K 2211/1018; H10K 50/11; H10K 2101/20

(57) ABSTRACT

The present invention provides a B/N organic electroluminescent material and its preparation method and use, as well as the corresponding organic light-emitting device. The B/N organic electroluminescent materials DBTN-1 and DBTN-2 in the present invention show narrowband green emission both in dilute solution and doped film, with extremely high photoluminescence quantum yields and efficient thermally activated delayed fluorescence feature. In particular, the organic light-emitting devices based on the above fluorescent dye exhibit ultra-pure green electroluminescence with high efficiencies and high color purity, which can be applied to usages such as ultra-high definition display technology.

This application is a Continuation Application of PCT/CN2022/101011, filed on Jun. 24, 2022, which claims priority to Chinese Patent Application No. 202111439232.3, filed on Nov. 29, 2021, which is incorporated by reference for all purposes as if fully set forth herein.

### FIELD OF THE INVENTION

The present invention relates to the technical field of organic luminescent dyes, in particular to a B/N organic electroluminescent material and a preparation method and use thereof.

### DESCRIPTION OF THE RELATED ART

Organic luminescent dyes have wide application value in electronic devices. For example, in an organic light-emitting device (OLED), carriers, i.e., electrons and holes, are injected respectively by applying a voltage across a cathode (Al) and an anode (ITO), wherein the electrons and holes pass through an electron transport layer (ETL) and a hole transport layer (HTL) respectively to reach a light-emitting layer (EML) containing an organic luminescent dye, and in the light-emitting layer (EML), the electrons and holes recombine to generate excitons for emitting photons outward in a fluorescence or phosphorescence process. OLED technology has the advantages such as wide viewing angle, ultra-thinness, fast response, high luminous efficiency, and flexible display. Furthermore, due to its large-area film-forming and low power consumption properties, it is also an ideal plane light source, which has broad application prospects in the future energy-saving and environment-friendly lighting field.

In recent years, thermally activated delayed fluorescence (TADF) materials have been widely developed and applied in electronic devices due to their effective utilization of triplet excitons. Particularly, in the field of OLED, such dyes can simultaneously use 25% singlet and 75% triplet excitons generated by electro-excitation to obtain high device efficiency. Up to now, the introduction of TADF materials as luminescent dyes in OLEDs can achieve high efficiency, but in most cases, the color purity is very poor, which cannot meet the technical requirements of ultra-high definition full-color display technology (Rec. 2020 standard). Therefore, a novel material system with high efficiency and high color purity needs to be developed urgently. In recent years, although a novel TADF material with multiple resonance effect (MR) has been reported to be capable of achieving emission with high color purity (Adv. Mater., 28, 2777-2781 (2016); Nat. Photonics (2019) DOI: 10.1038/s41566-019-0476-5; Angew. Chem. Int. Ed., 57, 11316-11320 (2018); Adv. Opt. Mater., 1801536 (2019); ACS Appl. Mater. Interfaces 11, 13472-13480 (2019)), the CIE of the green OLED device with the highest quality reported currently is only (0.16, 0.71) (Angew. Chem. Int. Ed., 60, 23142-23147), which is still far below the green standard of Rec. 2020 (the CIE is (0.20, 0.80), where CIE_{y} represents the ratio of green light in luminescence, and the higher the value, the purer the green light is). Therefore, it is necessary to develop a novel luminescent material with high efficiency and high color purity for ultra-pure green OLED devices towards ultra-high definition display technology.

### SUMMARY OF THE INVENTION

In order to solve the above technical problems, the present invention provides a B/N organic electroluminescent material and a preparation method and use thereof.

A novel B/N organic electroluminescent material is provided, wherein the B/N organic electroluminescent material includes DBTN-1 and/or DBTN-2, wherein the structural formulas of DBTN-1 and DBTN-2 are as follows:

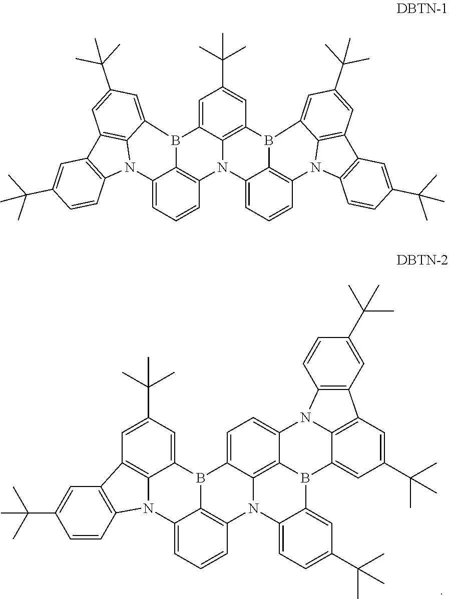

A method for preparing the novel B/N organic electroluminescent material is provided, including the following steps:
(1) mixing 2-fluoro-6-bromochlorobenzene, 3,6-di-tert-butylcarbazole and an alkali in an organic solvent for a carbon-nitrogen coupling reaction to produce

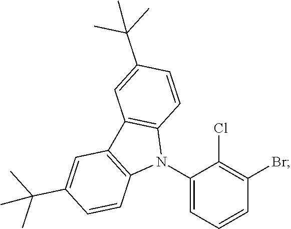 [SMILES: CC(C)(C)c1ccc2c(c1)c1cc(C(C)(C)C)ccc1n2-c1cccc(Br)c1Cl]

(2) subjecting

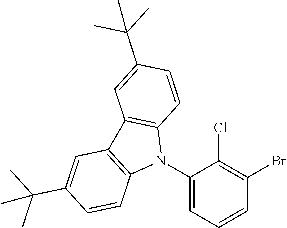 [SMILES: CC(C)(C)c1ccc2c(c1)c1cc(C(C)(C)C)ccc1n2-c1cccc(Br)c1Cl]

described in step (1) and 4-tert-butylaniline to a carbon-nitrogen coupling reaction in the presence of a metal catalyst and an alkali to obtain

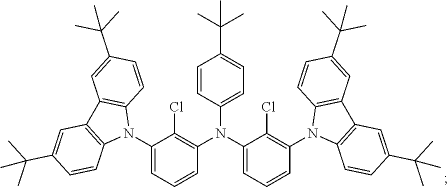 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]

(3) subjecting

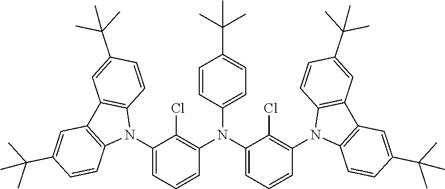 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]

and BBr₃ to a cyclization reaction with a lithium reagent in an ultra-dry reagent to obtain the B/N organic electroluminescent material.

In one example of the present invention, in step (1) or step (2), the alkali is selected from the group consisting of potassium tert-butoxide, sodium tert-butoxide, cesium carbonate and any combination thereof.

In one example of the present invention, in step (1), the organic solvent is selected from the group consisting of dimethylformamide, toluene, m-xylene and any combination thereof.

In one example of the present invention, in step (1), the molar ratio of the alkali to 3,6-di-tert-butylcarbazole is 1.5-2.5:1.

In one example of the present invention, in step (2), the molar ratio of the metal catalyst to

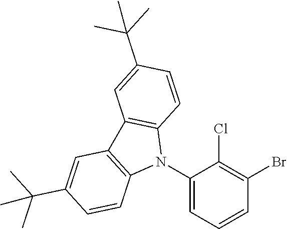 [SMILES: CC(C)(C)c1ccc2c(c1)c1cc(C(C)(C)C)ccc1n2-c1cccc(Br)c1Cl]

is 1:10-12.

In one example of the present invention, in step (2), the metal catalyst is selected from the group consisting of palladium chloride, palladium acetate, tris(dibenzylideneacetone)dipalladium, the ligand 2-dicyclohexylphosphino-2′,4′,6′-triisopropylbiphenyl and any combination thereof.

In one example of the present invention, in step (3), the lithium reagent is selected from the group consisting of tert-butyllithium, n-butyllithium, sec-butyllithium and any combination thereof.

In one example of the present invention, in step (3), the ultra-dry reagent is selected from the group consisting of tert-butylbenzene, o-xylene, trimethylbenzene and any combination thereof.

In one example of the present invention, in step (3), the molar ratio of the lithium reagent to

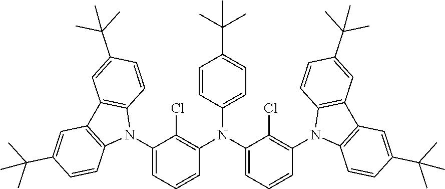 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]

is 5-6:1.

In one example of the present invention, in step (3), the B/N organic electroluminescent material obtained by the reaction is a mixture of DBTN-1 and DBTN-2, and the two are further separated by silica gel chromatography to obtain purified DBTN-1 and DBTN-2.

An organic electroluminescent device is provided, including the B/N organic electroluminescent material.

Compared with the prior art, the technical scheme of the present invention has the following advantages:

The novel B/N organic electroluminescent materials DBTN-1 and DBTN-2 provided in the present invention exhibit narrowband spectra with extremely small full width at half maxima (FWHM) values, extremely high photoluminescence quantum yields and efficient TADF feature in solution/doped thin films, so they can be used in OLEDs.

OLEDs based on DBTN-1 and DBTN-2 as emitter can realize ultra-pure green electroluminescence with high efficiency, high color purity and low efficiency roll-off. Therefore, the novel DBTN-1 and DBTN-2 of the present invention can be used as components of ultra-pure green OLEDs with high efficiency and high color purity.

### BRIEF DESCRIPTION OF THE DRAWINGS

In order to make the contents of the present invention easier to be understood clearly, the present invention will be further described in detail according to specific examples of the present invention with reference to the attached drawings, in which

FIG. 1 is a schematic cross-sectional view of the novel B/N organic electroluminescent materials DBTN-1 and DBTN-2 in the present invention applied to an OLED, wherein, 1. a glass substrate; 2. a hole transport layer; 3. an electron blocking layer; 4. a light-emitting layer; 5. an electron transport layer; and 6. a cathode layer;

FIG. 2 is a temperature-dependent transient decay curve of 2 wt % DBTN-2 doped in the 2-(9,9′-spiro[fluorene]-3-yl)-4,6-diphenyl-1,3,5-triazine (SF3-TRZ) film in Experimental Example 1.

### DETAILED DESCRIPTION OF THE PREFERRED EMBODIMENTS

The present invention will be further described with reference to the attached drawings and specific examples, so that those skilled in the art can better understand implement the present invention, but the examples given are not taken as limitations of the present invention.

### Example 1: Synthesis of DBTN-1 and DBTN-2

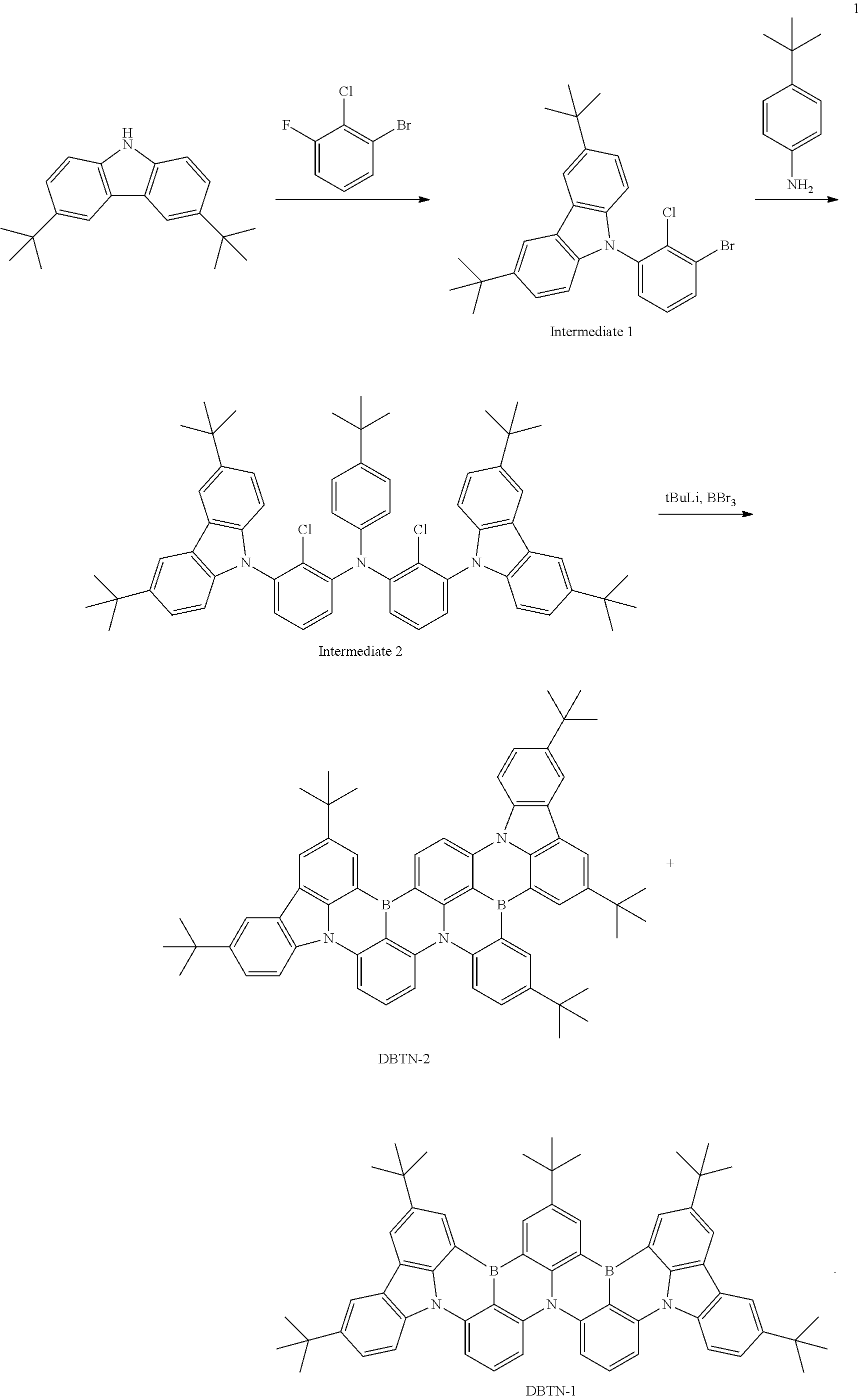

### Synthesis of Intermediate 1

Under nitrogen atmosphere, 5.6 g (20 mmol) of 3,6-di-tert-butylcarbazole, 4.2 g (20 mmol) of 2-fluoro-6-bromochlorobenzene, 9.8 g (30 mmol) of cesium carbonate and 200 mL of the ultra-dry N,N-dimethylformamide solvent were sequentially added into a 250 mL two-neck flask. After nitrogen replacement, the obtained reaction solution was heated to 150° C. and stirred for 24 hours. The reaction was cooled to room temperature, and slowly poured into 500 mL of deionized water, stirred and filtered to obtain a white filter cake. The obtained product was further purified by silica gel column with PE:DCM (6:1) as the eluent, to obtain 9.0 g white solid with a yield of 96%.

Product characterization: ¹H NMR (600 MHz, CDCl₃-d) δ 8.16 (dd, J=3.5, 1.8 Hz, 2H), 7.80 (dt, J=8.1, 1.2 Hz, 1H), 7.45 (ddt, J=8.2, 6.1, 1.7 Hz, 3H), 7.31 (t, J=8.0 Hz, 1H), 7.00 (dd, J=8.5, 2.0 Hz, 2H), 1.47 (d, J=2.6 Hz, 18H). ¹³C NMR (151 MHZ, CDCl₃-d) δ 143.13, 139.11, 137.28, 134.52, 133.58, 129.69, 128.31, 124.53, 123.70, 123.37, 116.37, 109.38, 34.75, 32.02. MS (MALDI-TOF). Calcd for C₂₆H₂₇BrClN: 468.86; Found: 468.69.

### 2. Synthesis of Intermediate 2

Under nitrogen atmosphere, 5.2 g (11 mmol) of Intermediate 1, 746 mg (5 mmol) of 4-tert-butylaniline, 458 mg (0.5 mmol) of tris(dibenzylideneacetone)dipalladium, 290 mg (1 mmol) of tri-tert-butylphosphine tetrafluoroborate, 2.0 g (30 mmol) of sodium tert-butoxide and 150 mL of the ultra-dry toluene solvent were sequentially added into a 250 mL two-neck flask. After being replaced with nitrogen for three times, the reaction solution was heated to reflux temperature and stirred for 24 hours. The reaction was cooled to room temperature, and then extracted with dichloromethane and deionized water. The organic phase was collected, dried with anhydrous sodium sulfate, and concentrated with rotary evaporator. The obtained product was further purified by silica gel column with PE:EA (4:1) as the eluent, to obtain 3.8 g white solid with a yield of 82%.

Product characterization: ¹H NMR (600 MHz, CDCl₃-d) δ 8.13 (t, J=1.7 Hz, 4H), 7.44-7.38 (m, 8H), 7.31 (ddt, J=16.5, 7.0, 2.2 Hz, 4H), 7.00 (d, J=8.6 Hz, 4H), 6.92 (dd, J=8.6, 1.5 Hz, 2H), 1.45 (d, J=1.5 Hz, 36H), 1.33 (s, 9H). ¹³C NMR (151 MHz, CDCl₃-d) δ 146.39, 145.60, 144.57, 142.76, 139.22, 137.62, 131.17, 128.20, 127.71, 126.65, 126.09, 123.55, 123.26, 121.13, 116.27, 109.43, 34.72, 34.28, 32.02, 31.44. MS (MALDI-TOF). Calcd for C₆₂H₆₇Cl₂N₃: 925.14; Found: 925.03.

### 3. Synthesis of Compound DBTN-2 and Compound DBTN-1

Under nitrogen atmosphere, 1.9 g (2 mmol) of Intermediate 2 and 60 mL of the ultra-dry tert-butyl benzene solvent were sequentially added into a 100 mL two-neck flask. After nitrogen replacement, the reaction solution was cooled to −40° C. Then, 3.1 mL of tert-butyllithium (5 mmol) in n-pentane (1.6 mol/L) was slowly added dropwise. After the reaction was stirred at 60° C. for 6 hours, the reaction solution was cooled to −40° C. again. Then, 0.5 mL of boron tribromide (5 mmol) was added dropwise, and warmed slowly to room temperature, and stirred for 6 hours. Subsequently, 0.8 mL of N,N-diisopropylethylamine was slowly added under the ice-water bath. Then the reaction solution was heated to 120° C. for 12 hours. The reaction was cooled to room temperature, and methanol was slowly added to quench the reaction, and then extracted with a large amount of dichloromethane and deionized water. The organic phase was collected, dried with anhydrous sodium sulfate, and concentrated with rotary evaporator. The obtained product was further purified by silica gel column with PE as the eluent, to obtain 80 mg orange solid DBTN-2 with a yield of 5% and 10 mg orange solid DBTN-1 with a yield of 1%, respectively.

Characterization of Compound DBTN-2: ¹H NMR (600 MHz, CDCl₃-d) δ 9.17 (dd, J=8.5, 1.6 Hz, 1H), 9.07 (d, J=1.8 Hz, 1H), 8.88 (d, J=1.8 Hz, 1H), 8.84 (d, J=2.4 Hz, 1H), 8.60 (dd, J=8.6, 2.2 Hz, 1H), 8.57-8.52 (m, 2H), 8.48 (d, J=1.8 Hz, 1H), 8.38 (d, J=8.6 Hz, 1H), 8.29 (d, J=2.0 Hz, 2H), 8.26 (dd, J=8.1, 2.0 Hz, 1H), 8.21-8.17 (m, 1H), 7.94 (d, J=8.3 Hz, 1H), 7.76-7.65 (m, 3H), 7.56 (dd, J=8.9, 2.5 Hz, 1H), 1.70 (s, 18H), 1.54 (s, 18H), 1.52 (s, 9H). ¹³C NMR (151 MHz, CDCl₃-d) δ 148.34, 147.54, 146.11, 145.90, 145.42, 145.11, 144.96, 144.89, 142.15, 141.46, 141.23, 138.54, 138.29, 131.59, 130.60, 129.78, 129.60, 127.55, 126.92, 124.54, 124.35, 124.09, 123.58, 122.64, 120.51, 120.19, 117.40, 117.18, 115.51, 114.73, 113.78, 108.76, 108.32, 35.29, 35.24, 34.83, 34.78, 34.62, 32.32, 32.25, 31.86, 31.81, 31.50. MS (MALDI-TOF). Calcd for C₆₂H₆₃B₂N₃: 871.83; Found: 871.48.

Characterization of Compound DBTN-1: ¹H NMR (600 MHZ, CDCl₃-d) δ 8.33 (d, J=2.4 Hz, 1H), 7.94-7.90 (m, 1H), 7.61 (d, J=7.7 Hz, 1H), 7.48 (dd, J=13.6, 7.1 Hz, 2H), 7.28-7.17 (m, 3H), 7.04 (dd, J=6.4, 1.3 Hz, 1H), 1.35 (s, 9H). ¹³C NMR (151 MHz, CDCl₃-d) δ 151.22, 150.94, 150.93, 148.05, 146.77, 146.39, 144.83, 144.04, 136.87, 133.91, 133.78, 130.88, 130.82, 130.51, 130.34, 130.25, 127.90, 127.00, 124.22, 122.55, 122.52, 121.61, 121.14, 118.87, 116.15, 115.57, 111.96, 35.99, 34.93, 31.34, 31.32, 31.28, 31.08. MS (MALDI-TOF). Calcd for C₆₂H₆₃B₂N₃: 871.83; Found: 871.54.

### Example 2

### 1. Synthesis of Intermediate 1

Under nitrogen atmosphere, 5.6 g (20 mmol) of 3,6-di-tert-butylcarbazole, 4.2 g (20 mmol) of 2-fluoro-6-bromochlorobenzene, (30 mmol) of potassium tert-butoxide and 200 mL of the ultra-dry N,N-dimethylformamide solvent were sequentially added into a 250 mL two-neck flask. After nitrogen replacement, the obtained reaction solution was heated to 150° C. and stirred for 24 hours. The reaction was cooled to room temperature, and then slowly poured into 500 mL of deionized water, stirred and filtered to obtain a white filter cake. The obtained product was further purified by silica gel column with PE:DCM (6:1) as the eluent, to obtain 9.6 g white solid.

### 2. Synthesis of Intermediate 2

Under the protection of nitrogen, 5.2 g (11 mmol) of Intermediate 1, 746 mg (5 mmol) of 4-tert-butylaniline, (0.5 mmol) of palladium acetate, 290 mg (1 mmol) of tri-tert-butylphosphine tetrafluoroborate, 2.0 g (30 mmol) of sodium tert-butoxide and 150 mL of the ultra-dry toluene solvent were sequentially added into a 250 mL two-neck flask. After being replaced with nitrogen for three times, the reaction solution was heated to reflux temperature and stirred for 24 hours. The reaction was cooled to room temperature, and then extracted with dichloromethane and deionized water. The organic phase was collected, dried with anhydrous sodium sulfate, and concentrated with a rotary evaporator. The obtained product was further purified by silica gel column with PE:EA (4:1) as the eluent, to obtain 4.2 g white solid.

### 3. Synthesis of Compound DBTN-2 and Compound DBTN-1

Under nitrogen atmosphere, 1.9 g (2 mmol) of Intermediate 2 and 60 mL of the ultra-dry tert-butyl benzene solvent were sequentially added into a 100 mL two-neck flask. After nitrogen replacement, the reaction solution was cooled to −40° C. Then, 3.1 mL of n-butyllithium (5 mmol) in n-pentane (1.6 mol/L) was slowly added dropwise. After the reaction was stirred at 60° C. for 6 hours, the reaction solution was cooled to −40° C. again. Then, 0.5 mL of boron tribromide (5 mmol) was added dropwise, and warmed slowly to room temperature, and stirred for 6 hours. Subsequently, 0.8 ml of N,N-diisopropylethylamine was slowly added under the ice-water bath. Then, the reaction solution was heated to 120° C. for 12 hours. The reaction was cooled to room temperature, and methanol was slowly added to quench the reaction, and then extracted with a large amount of dichloromethane and deionized water. The organic phase was collected, dried with anhydrous sodium sulfate, and concentrated with rotary evaporator. The obtained product was further purified by silica gel column with PE as the eluent, to obtain 75 mg orange solid DBTN-2 and 8.5 mg orange solid DBTN-1, respectively.

### Example 3

### 1. Synthesis of Intermediate 1

Under nitrogen atmosphere, 5.6 g (20 mmol) of 3,6-di-tert-butylcarbazole, 4.2 g (20 mmol) of 2-fluoro-6-bromochlorobenzene, (30 mmol) of sodium tert-butoxide and 200 mL of the ultra-dry m-xylene solvent were sequentially added into a 250 mL two-neck flask. After nitrogen replacement, the reaction solution was heated to 150° C. and stirred for 24 hours. The reaction was cooled to room temperature, and then slowly poured into 500 mL of deionized water, stirred and filtered to obtain a white filter cake. The obtained product was further purified by silica gel column with PE:DCM (6:1) as the eluent, to obtain 8.5 g white solid.

### 2. Synthesis of Intermediate 2

Under nitrogen, 5.2 g (11 mmol) of Intermediate 1, 746 mg (5 mmol) of 4-tert-butylaniline, (0.5 mmol) of palladium chloride, 290 mg (1 mmol) of tri-tert-butylphosphine tetrafluoroborate, 2.0 g (30 mmol) of sodium tert-butoxide and 150 mL of the ultra-dry toluene solvent were sequentially added into a 250 mL two-neck flask. After being replaced with nitrogen for three times, the reaction solution was heated to reflux temperature and stirred for 24 hours. The reaction was cooled to room temperature, and then extracted with dichloromethane and deionized water. The organic phase was collected, dried with anhydrous sodium sulfate, and concentrated with rotary evaporator. The obtained product was further purified by silica gel column with PE:EA (4:1) as the eluent, to obtain 4.0 g white solid.

### 3. Synthesis of Compound DBTN-2 and Compound DBTN-1

Under nitrogen atmosphere, 1.9 g (2 mmol) of Intermediate 2 and 60 mL of the ultra-dry o-xylene solvent were sequentially added into a 100 mL two-neck reaction bottle. After nitrogen replacement, the reaction solution was cooled to −40° C. Then, 3.1 mL of sec-butyllithium (5 mmol) in n-pentane (1.6 mol/L) was slowly added dropwise. After the reaction was stirred at 60° C. for 6 hours, the reaction solution was cooled to −40° C. again. Then, 0.5 mL of boron tribromide (5 mmol) was added dropwise, and warmed slowly to room temperature, and stirred for 6 hours. Subsequently, 0.8 mL of N,N-diisopropylethylamine was slowly added under the ice-water bath. Then the reaction solution was heated to 120° C. for 12 hours. The reaction was cooled to room temperature, and methanol was slowly added to quench the reaction, and then extracted with a large amount of dichloromethane and deionized water. The organic phase was collected, dried with anhydrous sodium sulfate, and concentrated with rotary evaporator. The obtained product was further purified by silica gel column with PE as the eluent, to obtain 85 mg orange solid DBTN-2 and 8.5 mg orange solid DBTN-1, respectively.

### Experimental Example 1

Photophysical characteristics of DBTN-2 obtained in Example 1 were investigated in toluene solution and in SF3-TRZ film with doping concentration of 2.5 wt %. The results are shown in Table 1.

TABLE 1

| Toluene solution | | | | In SF3-TRZ doped film | | | |
|---|---|---|---|---|---|---|---|
| λ_{abs} | λₑₘ | Stokes shift | FWHM | Es | E_{T} | ΔE_{ST} | |
| [nm] | [nm] | [nm] | [nm/meV] | [eV] | [eV] | [meV] | PLQY |
| 496 | 512 | 16 | 20/93 | 2.49 | 2.43 | 54 | 100% |

Wherein the Δ_{abs}, λₑₘ, Stokes shift, FWHM, E_{S}, E_{T}, ΔE_{ST}, and PLQY represent the peak position of absorption spectrum, the peak position of fluorescence spectrum, the stokes shift, the full width at half maxima of the spectrum, the energy level of the lowest excited singlet state, the energy level of the lowest excited triplet state, the energy level difference between the lowest excited singlet and the lowest excited triplet states, and the photoluminescence quantum yield, respectively. From the above results, it can be seen that the fluorescence spectrum of this material in dilute solution and doped film is in the green region, with an extremely small stokes shift, narrow FWHM and high luminescent efficiency.

The temperature-dependent transient decay curve of 2 wt % DBTN-2 doped SF3-TRZ film was further measured, as shown in FIG. 2. From the figure, it can be seen that it comprises obvious prompt and delayed fluorescence components, and the intensity of delayed fluorescence components increases obviously with the increased temperature, which proves that DBTN-2 has obvious TADF properties and can utilize triplet excitons effectively.

### Experimental Example 2

Taking the material of Example 1 as example, the fabrication and performance evaluation of organic electroluminescent devices were carried out.

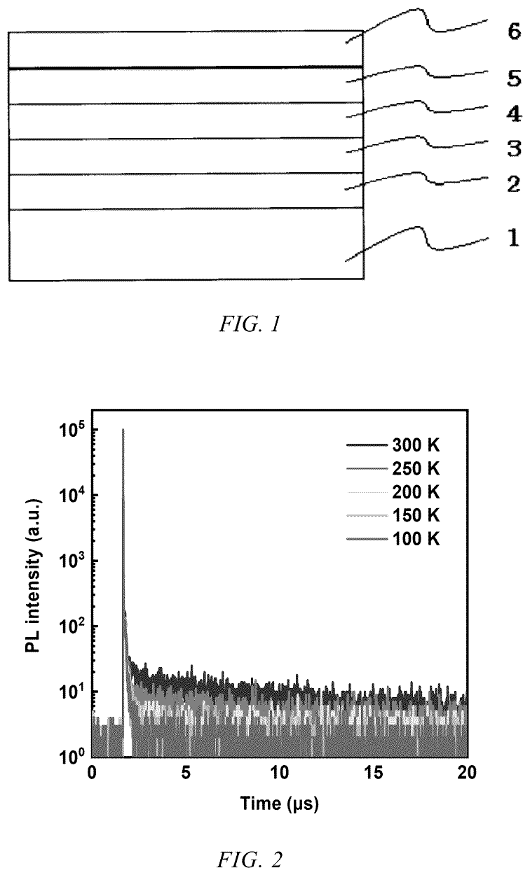

A glass plate with indium tin oxide (ITO) transparent electrodes was used as a substrate, wherein ITO pattern width is 3 mm. The substrate was washed with an ITO detergent and treated with ozone UV for 15 min. Then, the substrate was put into a vacuum evaporation chamber and vacuum evaporation method was used to evaporate each layer to fabricate an OLED device with a luminescent area of 10 mm² as shown in FIG. 1.

First, the aforementioned substrate was placed into a vacuum evaporation chamber and depressurized to 1×10⁻⁴ Pa. Then, on the glass substrate 1 shown in FIG. 1, films were formed sequentially as an organic compound layer into a hole-transporting layer 2, an electron-blocking layer 3, a light-emitting layer 4, and an electron-transporting layer 5, and then a film was formed with a cathode layer 6. 4,4′-cyclohexylbis[N,N-bis(4-methylphenyl)aniline] (TAPC) vacuum evaporated with a film thickness of 35 nm was used as the hole transport layer 2, tris(4-carbazolyl-9-ylphenyl)amine (TCTA) vacuum evaporated with a film thickness of 10 nm was used as the electron blocking layer 3, SF3-TRZ and the TADF material DBTN-2 synthesized in Example 1 of the present invention at a ratio of 97.5:2.5 (mass %) vacuum evaporated with a film thickness of 20 nm were used as the light-emitting layer 4,3,3′-[5′-[3-(3-pyridinyl)phenyl][1,1′:3′,1″-terphenyl]-3,3″-diyl]bispyridine (TmPyPb) vacuum evaporated with a film thickness of 40 nm was used as the electron transport layer 5. Wherein each organic materials were film-formed by means of thermo-resistive heating. The heated materials were vacuum evaporated at a film formation rate of 0.1-0.2 nm/s. Finally, a metal mask is configured orthogonal to the ITO stripes to form the film cathode 6. The cathode layer 6 is a two-layer structure formed by vacuum evaporating lithium fluoride and aluminum with film thicknesses of 1 nm and 100 nm, respectively. Each film thickness was measured with a stylus-type film thickness tester (DEKTAK). The devices were then sealed in a nitrogen atmosphere glove box with a water and oxygen concentration of 1 ppm or less. The encapsulation was performed using a glassy sealing cap and the aforementioned epoxy UV-curable resin (manufactured by Nagase ChemteX Corporation) for the ITO substrate.

A DC current was applied to the prepared OLED devices and the performance was evaluated using a Spectrascan PR655 luminometer, and the current-voltage characteristics were measured using a computer-controlled Keithley 2400 digital source meter. As luminescence characteristics, the electroluminescence spectra, FWHM, CIE coordinate values, maximum brightness (cd/m2), external quantum efficiency (%), and power efficiency (1 m/W) were measured under variations in response to the applied DC voltage. The measured values of the fabricated devices were a peak wavelength at 520 nm, with a half-peak width of 29 nm and CIE color coordinate of (0.19, 0.74), a maximum external quantum efficiency of 35.2%, a maximum current efficiency of 132.9 cd/A, and a maximum power efficiency of 130.4 lm/W.

In summary, the novel high-efficiency, high color purity narrowband organic electroluminescent materials DBTN-1 and DBTN-2 provided by the present invention can be applied in high-efficiency, high color purity ultrapure green OLEDs. The DBTN-1 and DBTN-2 involved in the present invention exhibit narrowband green emission with extremely high fluorescence quantum yields and efficient TADF properties both in dilute solution and doped films. In particular, the OLEDs prepared with the above fluorescent dyes have the advantages of high efficiency and ultra-pure green electroluminescence with high color purity, which can be applied to ultra-high definition display technology and other applications. By extension, the novel high-efficiency, high color purity narrowband organic electroluminescent material in the present invention can also be applied to a variety of host-guest organic electroluminescent devices such as fluorescent light-emitting materials and phosphorescent light-emitting materials, and can be applied to energy-saving lighting and the like, in addition to flat panel displays and the like.

Obviously, the above embodiments are merely examples for the sake of clarity, and are not a limitation of the embodiments. For a person of ordinary skill in the art, other variations or changes can be made on the basis of the above description. It is neither necessary nor possible to exhaust all the embodiments herein. The obvious variations or changes derived therefrom are still within the scope of protection of the present invention.

What is claimed is:

1. A B/N organic electroluminescent material, comprising DBTN-1 and/or DBTN-2, wherein structural formulas of DBTN-1 and DBTN-2 are as follows:

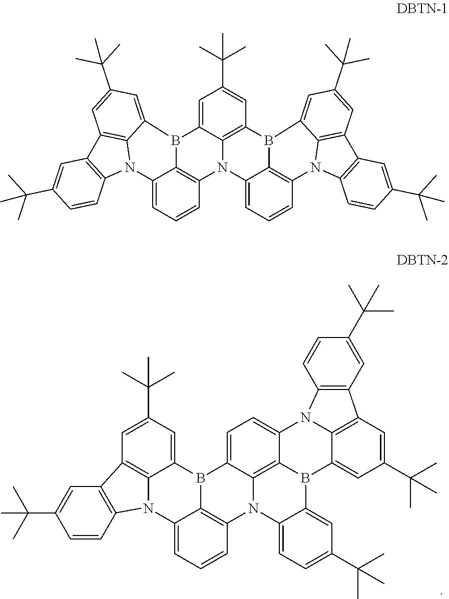

2. A method for preparing the B/N organic electroluminescent material according to claim 1, comprising steps of:
(1) mixing 2-fluoro-6-bromochlorobenzene, 3,6-di-tert-butylcarbazole and an alkali in an organic solvent for a carbon-nitrogen coupling reaction to produce 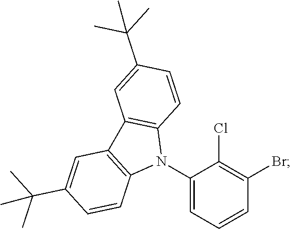 [SMILES: CC(C)(C)c1ccc2c(c1)c1cc(C(C)(C)C)ccc1n2-c1cccc(Br)c1Cl]
(2) subjecting 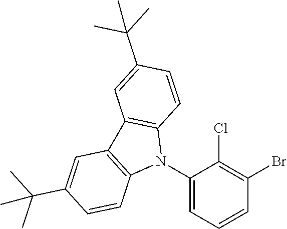 [SMILES: CC(C)(C)c1ccc2c(c1)c1cc(C(C)(C)C)ccc1n2-c1cccc(Br)c1Cl]
of step (1) and 4-tert-butylaniline to a carbon-nitrogen coupling reaction in the presence of a metal catalyst and an alkali to obtain 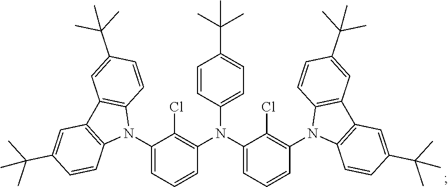 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]
(3) subjecting 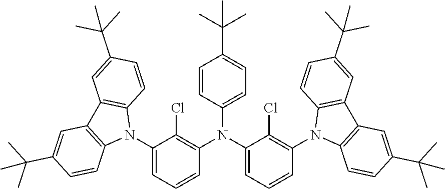 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]
and BBr₃ to a cyclization reaction with a lithium reagent in an ultra-dry reagent to obtain the B/N organic electroluminescent material.

3. The preparation method according to claim 2, wherein in step (1) or step (2), the alkali is selected from the group consisting of potassium tert-butoxide, sodium tert-butoxide, cesium carbonate and any combination thereof.

4. The preparation method according to claim 2, wherein in step (1), the organic solvent is selected from the group consisting of dimethylformamide, toluene, m-xylene and any combination thereof.

5. The preparation method according to claim 2, wherein in step (2), the molar ratio of the metal catalyst to 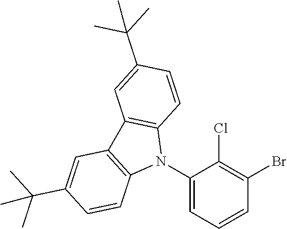 [SMILES: CC(C)(C)c1ccc2c(c1)c1cc(C(C)(C)C)ccc1n2-c1cccc(Br)c1Cl]
is 1:10-12.

6. The preparation method according to claim 2, wherein in step (2), the metal catalyst is selected from the group consisting of palladium chloride, palladium acetate, tris(dibenzylideneacetone)dipalladium, the ligand 2-dicyclohexylphosphino-2′,4′,6′-triisopropylbiphenyl and any combination thereof.

7. The preparation method according to claim 2, wherein in step (3), the lithium reagent is selected from the group consisting of tert-butyllithium, n-butyllithium, sec-butyllithium and any combination thereof.

8. The preparation method according to claim 2, wherein in step (3), the ultra-dry reagent is selected from the group consisting of tert-butylbenzene, o-xylene, trimethylbenzene and any combination thereof.

9. The preparation method according to claim 2, wherein in step (3), the molar ratio of the lithium reagent to 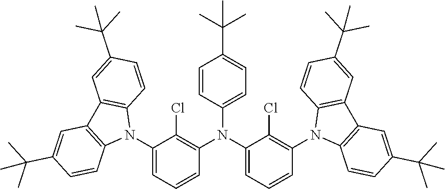 [SMILES: CC(C)(C)c1ccc(N(c2cccc(-n3c4ccc(C(C)(C)C)cc4c4cc(C(C)(C)C)ccc43)c2Cl)c2cccc(-n3c4ccc(C(C)(C)C)cc4c4cc(C(C)(C)C)ccc43)c2Cl)cc1]
is 5-6:1.

10. An organic light-emitting device, comprising the B/N organic electroluminescent material according to claim 1.
